(19) United States
(12) Patent Application Publication
(10) Pub. No.: US 2026/0068471 A1
(43) Pub. Date: Mar. 5, 2026

(54) ORGANIC LIGHT-EMITTING DISPLAY DEVICE

(71) Applicant: LG Display Co., Ltd., Seoul (KR)

(72) Inventor: Jungsik JO, Goyang-si (KR)

(73) Assignee: LG Display Co., Ltd., Seoul (KR)

(21) Appl. No.: 19/282,902

(22) Filed: Jul. 28, 2025

(30) Foreign Application Priority Data
Aug. 29, 2024 (KR) 10-2024-0117050

(51) Int. Cl. H10K 59/35

(52) U.S. Cl. CPC H10K 59/353; H10K 59/352

(57) ABSTRACT

An organic light-emitting display device includes a plurality of pixels arranged in a first direction and a second direction transverse to each other. Each pixel includes one first light-emitting region, two second light-emitting regions, and one third light-emitting region. The first to third light-emitting regions of one of two pixels adjacent along the first direction are arranged linearly symmetrically with respect to a first symmetry axis parallel to the second direction. Likewise, the first to third light-emitting regions of one of two pixels adjacent along the second direction are arranged linearly symmetrically with respect to a second symmetry axis parallel to the first direction. This configuration supports a high-resolution structure using conventional fine metal mask technology while reducing the likelihood of color mixture defects.

### CROSS-REFERENCE TO RELATED APPLICATION

This application claims priority from Korean Patent Application No. 10-2024-0117050 filed on August 29, 2024, in the Korean Intellectual Property Office, and all the benefits accruing therefrom under 35 U.S.C. 119, the contents of which in its entirety are herein incorporated by reference.

### BACKGROUND

### Technical Field

The present disclosure relates to an organic light-emitting display device.

### Description of Related Art

Display devices are applied to various electronic devices such as TV, mobile phones, laptops, and tablets.

The display device may include an organic light emitting display (OLED) that emits light by itself, and a liquid crystal display (LCD) that requires a separate light source, etc.

In the organic light-emitting display device, as an example, each sub-pixel includes a pixel circuit and an organic light-emitting diode whose operation is controlled by the pixel circuit. The organic light-emitting diode includes an anode electrode, an organic light-emitting layer, and a cathode electrode.

A fine metal mask is mainly used when the organic light-emitting layer is formed in each sub-pixel of the organic light-emitting diode, without being limited thereto.

The description provided in the background section should not be assumed to be prior art merely because it is mentioned in or associated with the background section. The background section may include information that describes one or more aspects of the subject technology.

### BRIEF SUMMARY

Various embodiments of the disclosed organic light-emitting display device provide a pixel arrangement that enables high resolution while remaining compatible with conventional fine metal mask technology. Each pixel includes multiple sub-pixels that are symmetrically arranged with respect to adjacent pixels, both along orthogonal directions and around central points. This symmetrical layout allows for efficient use of display area while maintaining sufficient separation between sub-pixels of different colors. As a result, it becomes possible to increase pixel density without increasing the risk of color mixing due to misalignment during manufacturing.

A continuous organic light-emitting layer is shared among four adjacent sub-pixels of the same color. This layer is deposited through a single enlarged opening in the fine metal mask, simplifying the deposition process and reducing reliance on precision patterning. By enabling the concurrent formation of same-color sub-pixels across multiple pixels, the approach significantly improves resolution while minimizing defects associated with alignment errors. The use of fewer, larger mask openings also enhances production efficiency and consistency.

The display structure allows variation in the shape and size of the sub-pixels, such as square, fan-shaped, or pentagonal forms. For example, increasing the area of blue-emitting sub-pixels reduces current density, which can help extend operational lifespan and achieve color balance over time. In addition, grouping sub-pixels of the same color into predefined regions aligned along structured lines enables consistent deposition and streamlined driving circuit design. This layout supports improved display performance while remaining compatible with established fabrication methods.

In order to increase the resolution of the organic light-emitting display device, fine processing of holes of a fine metal mask is required. In this regard, it is difficult to form fine holes due to limitations in manufacturing technology of the fine metal mask, such that it is difficult to implement a high-resolution organic light-emitting display device.

In addition, in order to reduce or prevent color mixture defects in which different organic light-emitting layers partially overlap in the light-emitting region of one sub-pixel due to manufacturing tolerances and alignment errors of the fine metal mask, a predetermined spacing (approximately 20 μm) between the light-emitting regions of the sub-pixels is required, and thus it is difficult to implement a high-resolution organic light-emitting diode display.

Accordingly, there is a need for a new scheme for manufacturing a high-resolution organic light-emitting display device.

The present disclosure relates to a high-resolution organic light-emitting display device that can be manufactured using a fine metal mask while reducing or preventing color mixture defects.

Technical benefits according to the present disclosure are not limited to the above-mentioned benefits. Other benefits and advantages according to the present disclosure that are not mentioned may be understood based on following descriptions, and may be more clearly understood based on embodiments according to the present disclosure. Further, it will be easily understood that the advantages according to the present disclosure may be realized using means shown in the claims or combinations thereof.

An organic light-emitting display device according to an exemplary embodiment of the present disclosure includes: a plurality of pixels arranged in a first direction and a second direction perpendicular to each other, wherein each of the pixels includes one first light-emitting region, two second light-emitting regions, and one third light-emitting region, wherein the first to third light-emitting regions of one of two pixels adjacent to each other along the first direction and the first to third light-emitting regions of the other of the two pixels adjacent to each other along the first direction are arranged linearly symmetrically with each other around a first symmetry axis parallel to the second direction, wherein the first to third light-emitting regions of one of two pixels adjacent to each other along the second direction and the first to third light-emitting regions of the other of the two pixels adjacent to each other along the second direction are arranged linearly symmetrically with each other around a second symmetry axis parallel to the first direction.

An organic light-emitting display device according to an exemplary embodiment of the present disclosure includes: first light-emitting region groups, each group including four first light-emitting regions spaced apart from each other; second light-emitting region groups, each group including four second light-emitting regions spaced apart from each other; and third light-emitting region groups, each group including four third light-emitting regions spaced apart from each other, wherein the first light-emitting region groups and the second light-emitting region groups are alternately arranged with each other along a first line extending in a first direction, wherein the second light-emitting region groups and the third light-emitting region groups are alternately arranged with each other along a second line, wherein the second line is spaced apart from the first line in a second direction perpendicular to the first direction and extends in the first direction and in parallel with the first line.

According to exemplary embodiments of the present disclosure, a pixel arrangement having a new structure in which a single organic light-emitting layer is continuously and commonly disposed across the respective sub-pixels emitting light of the same color of the four adjacent pixels may be applied, such that the resolution (pixel density) of the organic light-emitting display device may be improved four times even when a conventional fine metal mask is used.

According to exemplary embodiments of the present disclosure, since it is unnecessary to reduce the spacing between different light-emitting regions in each pixel to improve the resolution, it is possible to reduce or prevent color mixing defect due to an alignment error of the fine metal mask while improving the resolution.

According to exemplary embodiments of the present disclosure, the defect occurrence of the display device due to the color mixture defect is lowered, so that the production energy required for the production of the display device may be reduced and the emission of greenhouse gas may be reduced.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view of an organic light-emitting display device according to an exemplary embodiment of the present disclosure.

FIG. 2 is an enlarged view of an area ‘A1’ of FIG. 1.

FIG. 3 is a cross-sectional view taken along a line I-I′ of FIG. 2.

FIG. 4 illustrates a process of depositing a red organic light-emitting layer using a fine metal mask in an exemplary embodiment of the present disclosure.

FIG. 5 illustrates deposition of a green organic light-emitting layer using a fine metal mask in an exemplary embodiment of the present disclosure.

FIG. 6 shows that a blue organic light-emitting layer is deposited using a fine metal mask in an exemplary embodiment of the present disclosure.

FIGS. 7 to 12 are plan views illustrating pixel arrangements according to various exemplary embodiments of the present disclosure.

Throughout the drawings and the detailed description, unless otherwise described, the same drawing reference numerals should be understood to refer to the same elements, features, and structures.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify an entirety of the list of elements and may not modify the individual elements of the list.

In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween.

Further elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

In addition, it will also be understood that when an element or layer is referred to as being “between” two elements or layers, it may be the only element or layer between the two elements or layers, or one or more intervening elements or layers may also be present therebetween.

Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc., should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations. The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

When a first component or layer is described as “contacting” or “overlapping” a second component or layer, it should be understood that the first component or layer may directly contact or overlap the second component or layer, or a third component or layer may be interposed between the first and second components or layers that may indirectly contact or overlap each other unless otherwise specified.

Hereinafter, various exemplary embodiments of the present disclosure will be described in detail with reference to the accompanying drawings.

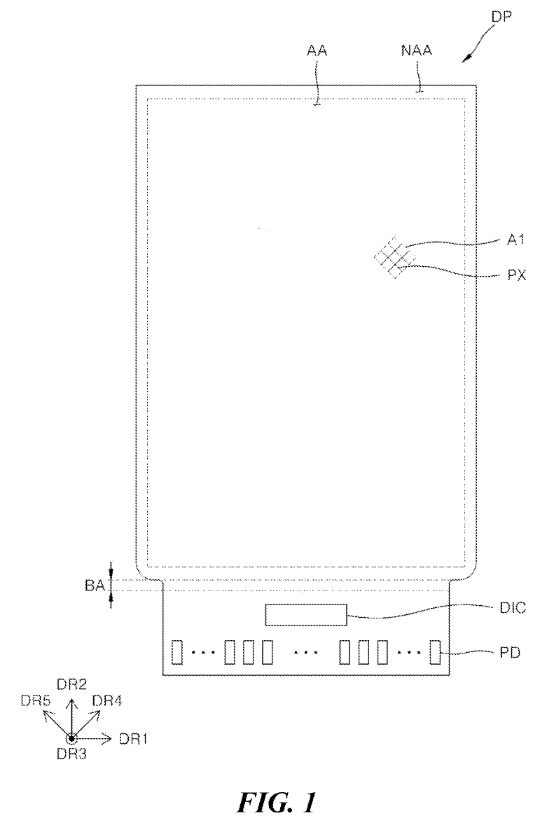

FIG. 1 is a plan view illustrating an organic light-emitting display device according to an exemplary embodiment of the present disclosure.

Referring to FIG. 1, the organic light-emitting display device may include a display panel DP and a driving circuit chip DIC. The display panel DP may include a display area AA in which a plurality of pixels PX are disposed and a non-display area NAA. As an example, a plurality of pads PD may be disposed in the non-display area NAA, without being limited thereto.

The display area AA may have a rectangular shape defined by a first direction DR1 and a second direction DR2. The first direction DR1 may be a direction parallel to an upper side and a lower side of the display area AA, and the second direction DR2 may be a direction parallel to a left side and a right side of the display area AA. The third direction DR3 may be a direction perpendicular to a plane defined by the first direction DR1 and the second direction DR2.

The shape in the plan view of the display area AA illustrated in FIG. 1 is merely an example, and the shape in the plan view of the display area AA may vary without limitation as needed. The non-display area NAA is an area which is disposed around the display area AA, and in which no image is displayed. The non-display area NAA may fully or partially surround the display area AA. As an example, the shape in the plan view of the display area AA may be a square shape, a circular shape, an oval shape, a polygonal shape, a triangle shape, etc., without being limited thereto. As an example, the non-display area NAA may be extended from the display area AA. As an example, the non-display area NAA may be at least partially or entirely invisible from a front side of the display panel DP, for example, by being bent toward a rear side of the display panel DP, without being limited thereto.

Lines for providing an electrical signal to the display area AA or receiving an electrical signal from the display area AA may be disposed in the non-display area NAA. As an example, a gate driver (not shown) for supplying a gate signal to the plurality of pixels PX of the display area AA may be disposed in the non-display area NAA, without being limited thereto. The gate driver may be disposed at one side or each of both opposing sides of the non-display area NAA of the display panel DP in a gate driver in panel (GIP) manner. Alternatively, the gate driver may be separately disposed in a separate panel or film and connected to the display panel DP (e.g., the pads PD), for example, in a tape automated bonding (TAB) method, a chip on glass (COG) method, a chip on panel (COP) method, or a chip on film (COF) method, without being limited thereto.

As an example, the driving circuit chip DIC may be mounted in or connected to the non-display area NAA of the display panel DP via an anisotropic conductive film, without being limited thereto. The driving circuit chip DIC may be a data driving circuit chip.

A printed circuit board (not shown) may be electrically connected to the plurality of pads PD via an anisotropic conductive film. The printed circuit board may be a flexible printed circuit board, without being limited thereto. As an example, a timing controller chip may be mounted on the printed circuit board, without being limited thereto.

As an example, a bendable area BA of the display panel DP may be bent so that the driving circuit chip DIC may be disposed under the display area AA of the display panel DP. Accordingly, a size of the non-display area NAA of the organic light-emitting display device visually recognized by the user may be reduced. Embodiments are not limited thereto. As an example, the bendable area BA may be omitted depending on the design.

The bendable area BA may be an area located between the display panel DP and the driving circuit chip DIC.

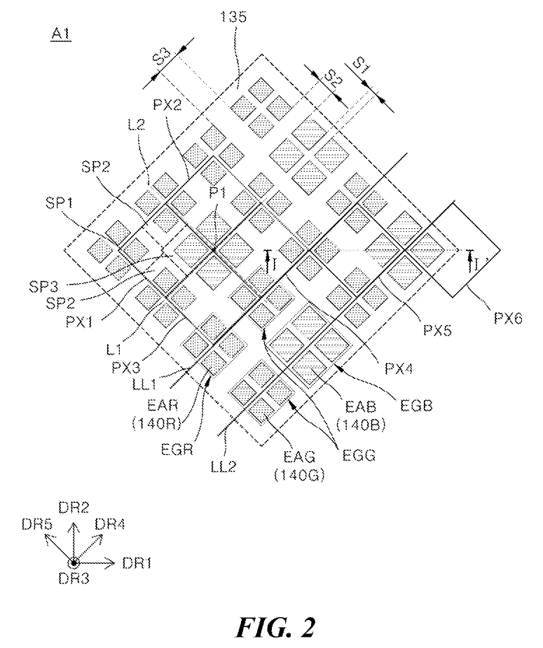

FIG. 2 is an enlarged view of an area ‘A1’ of FIG. 1.

Referring to FIG. 2, as an example, the organic light-emitting display device includes a plurality of pixels PX arranged in a fourth direction DR4 and a fifth direction DR5 intersecting (e.g., perpendicular to) the fourth direction. The fourth direction DR4 may be a direction between the first direction DR1 and the second direction DR2. For example, the fourth direction DR4 may define 45 degrees relative to the first direction DR1, or may define 10 degrees, 30 degrees, 60degress, or 75 degrees relative to the first direction DR1, without being limited thereto. For example, the fifth direction DR5 may be a direction perpendicular to the fourth direction DR4 and may define 45 degrees relative to the second direction DR2, or may define 10 degrees, 30 degrees, 60degress, or 75 degrees relative to the second direction DR2, without being limited thereto. Each pixel PX may have a virtual quadrangular shape having four sides, two opposing sides thereof parallel to the fourth direction DR4 and two opposing sides thereof parallel to the fifth direction DR5. Each pixel PX may have, for example, a virtual square shape. In FIG. 2, for convenience of illustration, a first pixel PX1, a second pixel PX2, a third pixel PX3, a fourth pixel PX4, a fifth pixel PX5, and a sixth pixel PX6 are shown. In the present disclosure, the ‘first direction’, the ‘second direction’, the ‘third direction’, the ‘fourth direction’, and the ‘fifth direction’ are merely for distinguishing different directions from each other.

As an example, each pixel PX includes four sub-pixels SP1, SP2, and SP3. As an example, each pixel PX may include one first sub-pixel SP1, two second sub-pixels SP2, and one third sub-pixel SP3. In each pixel PX, as an example, the first sub-pixel SP1 and the third sub-pixel SP3 may face each other, and two second sub-pixels SP2 may face each other. As an example, the first sub-pixel SP1 and the third sub-pixel SP3 may face each other in the first direction DR1, and two second sub-pixels SP2 may face each other in the second direction DR2. Embodiments are not limited thereto. As an example, each pixel PX may include one or more sub-pixel, three or more sub-pixels or five or more sub-pixels. As an example, the three or more sub-pixels included in one pixel PX may emit light of different colors, or at least two of the three or more sub-pixels included in one pixel PX may emit light of the same color. As an example, the arrangement of the three or more sub-pixels included in one pixel PX may be varied in various ways. As an example, the first sub-pixel SP1 and the third sub-pixel SP3 may face each other in a direction other than the first direction DR1 and the second direction DR2, without being limited thereto.

The first sub-pixel SP1 may include a first light-emitting region EAR that emits light of a first color. The second sub-pixel SP2 may include a second light-emitting region EAG that emits light of a second color. The third sub-pixel SP3 may include a third light-emitting region EAB that emits light of a third color. For example, the first sub-pixel SP1 may be a red sub-pixel, the second sub-pixel SP2 may be a green sub-pixel, and the third sub-pixel SP3 may be a blue sub-pixel. In this case, the first light-emitting region EAR may include a first light-emitting element 140R that emits red light, the second light-emitting region EAG may include a second light-emitting element 140G that emits green light, and the third light-emitting region EAB may include a third light-emitting element 140B that emits blue light. Embodiments are not limited thereto. As an example, a sub-pixel that emits light of a color other than red, green, or blue may be additionally or alternatively included.

The respective first to third light-emitting regions EAR, EAG, and EAB of the first to third sub-pixels SP1, SP2, and SP3 may be disposed adjacent to four corners of each pixel PX, respectively. As an example, the first to third light-emitting regions EAR, EAG, and EAB of the first to third sub-pixels SP1, SP2, and SP3 may have the same shape or may have different shapes. However, embodiments of the present disclosure are not limited thereto. As an example, each of the first to third light-emitting regions EAR, EAG, and EAB of the first to third sub-pixels SP1, SP2, and SP3 may have a quadrangular shape, without being limited thereto. As an example, each of the first to third light-emitting regions EAR, EAG, and EAB of the first to third sub-pixels SP1, SP2, and SP3 may have various shape such as a circular shape, an oval shape, a polygonal shape, a triangle shape, or a square shape.

When the first sub-pixel SP1 is a red sub-pixel, the second sub-pixel SP2 is a green sub-pixel, and the third sub-pixel SP3 is a blue sub-pixel, as an example, an area in the plan view of the third light-emitting region EAB of the third sub-pixel SP3 may be greater than an area in the plan view of the first light-emitting region EAR of the first sub-pixel SP1, without being limited thereto. As an example, an area in the plan view of the third light-emitting region EAB of the third sub-pixel SP3 may be, for example, twice an area in the plan view of the first light-emitting region EAR of the first sub-pixel SP1, without being limited thereto. The area in the plan view of the second light-emitting region EAG of the second sub-pixel SP2 may be, for example, equal to as an area in the plan view of the first light-emitting region EAR of the first sub-pixel SP1, without being limited thereto. However, embodiments of the present disclosure are not limited thereto. When an area in the plan view of the second light-emitting region EAG of the second sub-pixel SP2 is equal to an area in the plan view of the first light-emitting region EAR of the first sub-pixel SP1, as an example, a total area in the plan view of the two second light-emitting regions EAG may be twice the area in the plan view of the first light-emitting region EAR of the first sub-pixel SP1. Embodiments are not limited thereto. As an example, an area in the plan view of the third light-emitting region EAB of the third sub-pixel SP3, an area in the plan view of the second light-emitting region EAG of the second sub-pixel SP2 and an area in the plan view of the first light-emitting region EAR of the first sub-pixel SP1 may be equal to each other or may be different from each other, without being limited thereto.

Since the area in the plan view of the blue light-emitting region EAB is designed to be larger, the current density supplied to the light-emitting element disposed in the blue light-emitting region EAB may be the smaller. Accordingly, a lifespan of the light-emitting element disposed in the blue light-emitting region EAB may be similar to or longer than a lifespan of the light-emitting element disposed in the red light-emitting region EAR, such that a lifespan of the organic light-emitting display device according to an exemplary embodiment of the present disclosure may be improved.

The first pixel PX 1 and the second pixel PX 2 may be two pixels adjacent to each other along the fourth direction DR4. The third pixel PX 3 and the fourth pixel PX 4 may be two pixels adjacent to each other along the fourth direction DR4. In this regard, the first to third light-emitting regions EAR, EAG, and EAB of one of the two pixels adjacent to each other along the fourth direction DR4 may be arranged linearly symmetrically with the first to third light-emitting regions EAR, EAG, and EAB of the other of the two pixels adjacent to each other along the fourth direction DR4 around a symmetry axis L2 parallel to the fifth direction DR5.

The first pixel PX1 and the third pixel PX3 may be two pixels adjacent to each other along the fifth direction DR5. The second pixel PX2 and the fourth pixel PX4 may be two pixels adjacent to each other along the fifth direction DR5. In this regard, the first to third light-emitting regions EAR, EAG, and EAB of one of the two pixels adjacent to each other along the fifth direction DR5 may be arranged linearly symmetrically with the first to third light-emitting regions EAR, EAG, and EAB of the other of the two pixels adjacent to each other along the fifth direction DR5 around a symmetry axis L1 parallel to the fourth direction DR4.

The four light-emitting regions emitting light of the same color of four adjacent pixels PX may be disposed adjacent to each other. Four first light-emitting regions EAR emitting red light of four adjacent pixels may be disposed adjacent to each other. Four second light-emitting regions EAG emitting green light of four adjacent pixels may be disposed adjacent to each other. Four third light-emitting regions EAB that emit blue light of four adjacent pixels may be disposed adjacent to each other.

The four light-emitting regions EA that emit light of the same color and are disposed adjacent to each other may have the same shape, and may be arranged so as to be linearly-symmetrical with each other around each of the symmetry axes L1 and L2 respectively parallel to the fourth direction DR4 and the fifth direction DR5. The four first light-emitting regions EAR that emit red light and are disposed adjacent to each other may have the same shape, and may be arranged so as to be linearly-symmetrical with each other around each of the symmetry axes L1 and L2 respectively parallel to the fourth direction DR4 and the fifth direction DR5. The four second light-emitting regions EAG that emit green light and are disposed adjacent to each other may have the same shape, and may be arranged so as to be linearly-symmetrical with each other around each of the symmetry axes L1 and L2 respectively parallel to the fourth direction DR4 and the fifth direction DR5. The four third light-emitting regions EAB that emit blue light and are disposed adjacent to each other may have the same shape, and may be arranged so as to be linearly-symmetrical with each other around each of the symmetry axes L1 and L2 respectively parallel to the fourth direction DR4 and the fifth direction DR5.

The first to fourth pixels PX1, PX2, PX3, and PX4 adjacent to each other will be described by way of example. The four third light-emitting regions EAB emitting blue light may be disposed adjacent to each other. The four third light-emitting regions EAB that emit blue light and are disposed adjacent to each other may have the same shape. The third light-emitting region EAB of the first pixel PX1 and the third light-emitting region EAB of the third pixel PX3 may be arranged so as to be linearly-symmetrical with each other around the symmetry axis L1 parallel to the fourth direction DR4, and the third light-emitting region EAB of the second pixel PX2 and the third light-emitting region EAB of the fourth pixel PX4 may be arranged so as to be linearly-symmetrical, around the symmetry axis L1 parallel to the fourth direction DR4. In addition, the third light-emitting region EAB of the first pixel PX1 and the third light-emitting region EAB of the second pixel PX2 may be arranged so as to be linearly-symmetrical around the symmetry axis L2 parallel to the fifth direction DR5, and the third light-emitting region EAB of the second pixel PX2 and the third light-emitting region EAB of the fourth pixel PX4 may be arranged so as to be linearly-symmetrical with each other around the symmetry axis L2 parallel to the fifth direction DR5.

In addition, the respective first to third light-emitting regions EAR, EAG, and EAB of one of the four pixels PX adjacent to each other and the respective first to third light-emitting regions EAR, EAG, and EAB of another of the four pixels PX adjacent to each other may be arranged so as to be rotationally-symmetrical with each other, respectively, around a symmetry point between the four pixels PX. The first to fourth pixels PX1, PX2, PX3, and PX4 adjacent to each other will be described by way of example. The first to third light-emitting regions EAR, EAG, and EAB of one of the first to fourth pixels PX1, PX2, PX3, and PX4 and the first to third light-emitting regions EAR, EAG, and EAB of another of the first to fourth pixels PX1, PX2, PX3, and PX4 may be arranged so as to be rotationally-symmetrical with each other, respectively, around a symmetry point P1 between the first to fourth pixels PX1, PX2, PX3, and PX4. The first to third light-emitting regions EAR, EAG, and EAB of the first pixel PX1 may respectively have a 90-degree rotational symmetry relationship with the first to third light-emitting regions EAR, EAG, and EAB of the second pixel PX2, respectively. The first to third light-emitting regions EAR, EAG, and EAB of the first pixel PX1 may respectively have a 180-degree rotational symmetry relationship with the first to third light-emitting regions EAR, EAG, and EAB of the fourth pixel PX4, respectively.

As an example, a spacing between two light-emitting regions emitting light of the same color of two adjacent pixels may be smaller than a spacing between two light-emitting regions emitting light of different colors in each pixel. For example, the first pixel PX1 and the third pixel PX3 adjacent to each other will be described by way of example. A spacing S1 between two third light-emitting regions EAB emitting blue light of the first pixel PX1 and the third pixel PX3 may be smaller than a spacing S2 between the second light-emitting region EAG and the third light-emitting region EAB in the first pixel PX1 or the third pixel PX3. The spacing S1 between two third light-emitting regions EAB emitting blue light of the first pixel PX1 and the third pixel PX3 may be smaller than a spacing S3 between the first light-emitting region EAR and the second light-emitting region EAG in the first pixel PX1 or the third pixel PX3. Embodiments are n limited thereto. As an example, a spacing between two light-emitting regions emitting light of the same color of two adjacent pixels may be equal to or greater than a spacing between two light-emitting regions emitting light of different colors in each pixel, without being limited thereto.

As will be described later, as an example, an organic light-emitting layer emitting light of the same color may be continuously and commonly disposed across the four light-emitting regions disposed adjacent to each other. Accordingly, a spacing between the light-emitting regions emitting light of the same color of the pixels PX adjacent to each other may be formed to be smaller regardless of the alignment error of the fine metal mask. Embodiments are not limited thereto. As an example, an organic light-emitting layer emitting light of the same color may be separately disposed for at least some of or each of the four light-emitting regions disposed adjacent to each other, without being limited thereto.

As an example, the organic light-emitting display device may include first light-emitting region groups EGR, each including four first light-emitting regions EAR spaced apart from each other, second light-emitting region groups EGG, each including four second light-emitting regions EAG spaced apart from each other, and third light-emitting region groups EGB, each including four third light-emitting regions EAB spaced apart from each other. For example, the first light-emitting regions EAR may be red light-emitting regions, the second light-emitting regions EAG may be green light-emitting regions, and the third light-emitting regions EAB may be blue light-emitting regions.

The first light-emitting region groups EGR and the second light-emitting region groups EGG may be alternately arranged with each other along a first line LL1 extending in the fourth direction DR4. In addition, the second light-emitting region groups EGG and the third light-emitting region groups EGB may be alternately arranged with each other along a second line LL2 spaced apart from the first line LL1 in a fifth direction DR5 orthogonal to the fourth direction DR4 and extending in the fourth direction DR4 in parallel to the first line LL1.

The four first light-emitting regions EAR of the first light-emitting region group EGR may have the same shape, for example, a square shape, and may be arranged so as to be linearly-symmetrical with each other around each of the symmetry axes L1 and L2 respectively parallel to the fourth direction DR4 and the fifth direction DR5. The four second light-emitting regions EAG of the second light-emitting region group EGG may have the same shape, for example, a square shape, and may be arranged so as to be linearly-symmetrical with each other around each of the symmetry axes L1 and L2 respectively parallel to the fourth direction DR4 and the fifth direction DR5. The four third light-emitting regions EAB of the third light-emitting region group EGB may have the same shape, for example, a square shape, and may be arranged so as to be linearly-symmetrical with each other around each of the symmetry axes L1 and L2 respectively parallel to the fourth direction DR4 and the fifth direction DR5.

The organic light-emitting layer emitting light of a first color, for example, red, may be continuously and commonly disposed across four first light-emitting regions EAR of the first light-emitting region group EGR. The organic light-emitting layer emitting lights of a second color, for example, green, may be continuously and commonly disposed across four second light-emitting regions EAG of the second light-emitting region group EGG. The organic light-emitting layer emitting light of a third color, for example, blue, may be continuously and commonly disposed across four third light-emitting regions EAB of the third light-emitting region group EGB.

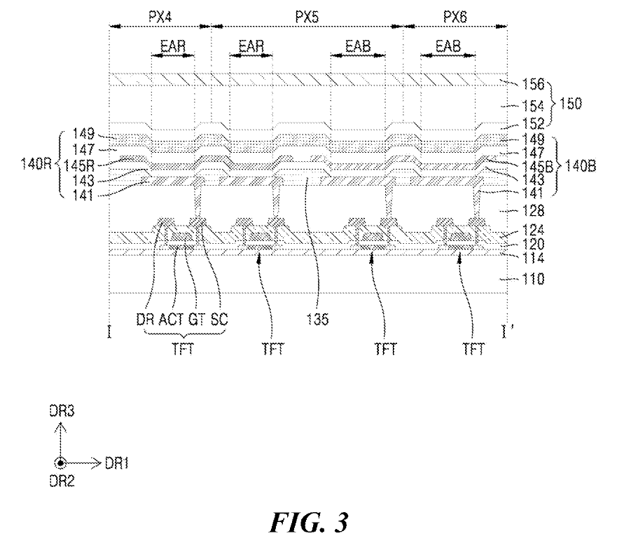

FIG. 3 is a cross-sectional view taken along a line I-I′ of FIG. 2.

Referring to FIG. 3, the organic light-emitting display device may include a plurality of thin-film transistors TFT and a plurality of light-emitting elements 140R, 140G, and 140B disposed on a substrate 110. At least one thin-film transistor and one light-emitting element may be disposed in each sub-pixel. In FIG. 3, the first light-emitting element 140R and the third light-emitting element 140B are illustrated by way of example.

As an example, the substrate 110 may be a flexible substrate or a rigid substrate. As an example, the substrate 110 may be a flexible substrate. As an example, the substrate 110 may be made of, for example, an organic insulating material such as polyimide. The substrate 110 may be implemented as, for example, a multilayer stack in which organic insulating material layers and inorganic insulating material layers are alternately stacked on top of each other, or implemented as a single layer. For example, the substrate 110 may be formed by alternately stacking the organic insulating material layers made of, for example, polyimide and the inorganic insulating material layers made of, for example, silicon oxide (SiOx). For example, the substrate 110 may have a three-layer structure in which a silicon oxide layer is disposed between two polyimide layers, without being limited thereto.

A buffer layer 114 is formed on the substrate 110. The buffer layer 114 may be embodied as a single layer or a multilayer stack made of an inorganic insulating material such as silicon oxide (SiOx) or silicon nitride (SiNx), without being limited thereto.

A plurality of thin-film transistors TFT may be disposed on the buffer layer 114. At least one thin-film transistor TFT may be disposed in each sub-pixel. The thin-film transistor TFT includes an active layer ACT made of a semiconductor material such as a polycrystalline semiconductor material, an oxide semiconductor material, a compound semiconductor material and an organic semiconductor material, etc., a gate electrode GT overlapping a channel area of the active layer ACT, a source electrode SC connected to a source area of the active layer ACT, and a drain electrode DR connected to a drain area of the active layer ACT.

The active layer ACT may be disposed on the buffer layer 114. A gate insulating layer 120 is disposed between the gate electrode GT and the active layer ACT. The gate insulating layer 120 may be disposed on the buffer layer 114 while covering the active layer ACT. The light insulating layer 120 may be embodied as a single layer or a multilayer stack made of an inorganic insulating material such as silicon oxide (SiOx) or silicon nitride (SiNx), without being limited thereto.

The gate electrode GT may be embodied as a single layer or a multilayer stack made of one of molybdenum (Mo), aluminum (Al), chromium (Cr), gold (Au), titanium (Ti), nickel (Ni), neodymium (Nd), and copper (Cu) or an alloy thereof. However, embodiments of the present disclosure are not limited thereto.

An interlayer insulating layer 124 may be disposed on the gate electrode GT. The interlayer insulating layer 124 may be embodied as a single layer or a multilayer stack made of an inorganic insulating material such as silicon oxide (SiOx) or silicon nitride (SiNx), without being limited thereto.

The source electrode SC and the drain electrode DR may be disposed on the interlayer insulating layer 124. The source electrode SC and the drain electrode DR may be electrically connected to the source area and the drain area of the active layer ACT, respectively, through respective through-holes extending through the interlayer insulating layer 124 and the gate insulating layer 120.

A planarization layer 128 may be disposed to planarize a step caused by the thin-film transistor TFT. The planarization layer 128 may be made of an organic insulating material such as polyimide or acrylic resin, without being limited thereto.

The first to third light-emitting elements 140R, 140G, and 140B may be formed on the planarization layer 128. In FIG. 3, the first light-emitting element 140R and the third light-emitting element 140B are illustrated by way of example, and the second light-emitting element 140G is not illustrated. The first light-emitting element 140R may be disposed in the first light-emitting region EAR, the second light-emitting element 140G may be disposed in the second light-emitting region EAG, and the third light-emitting element 140B may be disposed in the third light-emitting region EAB.

As an example, the first light-emitting element 140R may include an anode electrode 141, a lower common layer 143, a first organic light-emitting layer 145R, an upper common layer 147, and a cathode electrode 149. For example, the first organic light-emitting layer 145R may emit red light. The third light-emitting element 140B may include an anode electrode 141, a lower common layer 143, a third organic light-emitting layer 145B, an upper common layer 147, and a cathode electrode 149. For example, the third organic light-emitting layer 145B may emit blue light. Although not shown, the second light-emitting element 140G may include an anode electrode 141, a lower common layer 143, a second organic light-emitting layer, an upper common layer 147, and a cathode electrode 149. For example, the second organic light-emitting layer may emit green light. Embodiments are not limited thereto. As an example, at least one of or both of the lower common layer 143 and the upper common layer 147 of at least one of or each of the first light-emitting element 140R, the second light-emitting element 140G, and the third light-emitting element 140B may be omitted depending on the design.

One anode electrode 141 may be disposed in each sub-pixel. The anode electrode 141 may be electrically connected to the source electrode SC or the drain electrode DR of the thin-film transistor TFT via a through-hole extending through the planarization layer 128.

As an example, the anode electrode 141 may be formed in a single layer structure or a multilayer structure including a conductive material. As an example, the anode electrode 141 may be formed in a multilayer structure including a transparent conductive film and an opaque conductive film having high reflection efficiency, without being limited thereto. As an example, the transparent conductive film may be made of a material having a relatively high work function value, such as indium-tin-oxide (ITO) or indium-zinc-oxide (IZO), and the opaque conductive film may be made of a single-layer or multi-layer structure including aluminum (Al), silver (Ag), copper (Cu), lead (Pb), molybdenum (Mo), titanium (Ti), or an alloy thereof. For example, the anode electrode 141 may be formed in a structure in which a transparent conductive film, an opaque conductive film, and a transparent conductive film are sequentially stacked, or may be formed in a structure in which a transparent conductive film and an opaque conductive film are sequentially stacked, without being limited thereto.

A bank layer 135 may be disposed on the planarization layer 128. The bank layer 135 may act as a pixel defining layer that exposes a partial area (e.g., a central area) of each anode electrode 141. The bank layer 135 may be made of an organic insulating material. The bank layer 135 may include, for example, one of photosensitive polyimide, photoacryl, and benzocyclobutene (BCB). The bank layer 135 may be made of an opaque material to reduce or prevent optical interference between adjacent pixels. In this case, as an example, the bank layer 135 may include a light-shielding material made of at least one of a color pigment, organic black pigment, and carbon.

As an example, a spacer (not shown) may be further disposed on the bank layer 135. A fine metal mask may be used to form the organic light-emitting layers. The spacer may maintain a predetermined spacing between the bank layer 135 and the fine metal mask to reduce or prevent damage to the bank layer 135 and the anode electrodes 141 that may be caused by contact with the fine metal mask. As an example, the spacer may be omitted depending on the design.

The lower common layer 143 may be disposed on the anode electrodes 141 and the bank layer 135. As an example, the lower common layer 143 may be continuously and commonly disposed across all pixels of the display area AA. As an example, the lower common layer 143 may include a hole injection layer and a hole transport layer. Embodiments are not limited thereto. As an example, the lower common layer 143 may be separately disposed for each of pixels of the display area AA, or may be separately disposed for each light-emitting region group, without being limited thereto. As an example, the lower common layer 143 may be continuously and commonly disposed across all light-emitting regions of each light-emitting region group, without being limited thereto.

, The first organic light-emitting layer 145R may be continuously and commonly disposed across four first light-emitting regions EAR that belong to different pixel but are adjacent to each other. FIG. 3 illustrates that the first organic light-emitting layer 145R is continuously and commonly disposed across the first light-emitting regions EAR belonging to the fourth pixel PX4 and the fifth pixel PX5 but adjacent to each other. The third organic light-emitting layer 145B may be continuously and commonly disposed across four adjacent third light-emitting regions EAB that belong to different pixel but are adjacent to each other. FIG. 3 illustrates that the third organic light-emitting layer 145B is continuously and commonly disposed across the third light-emitting regions EAB belonging to the fifth pixel PX5 and the sixth pixel PX6 but adjacent to each other. Similarly, the second organic light-emitting layer may be continuously and commonly disposed across four second light-emitting regions EAG that belong to different pixels but are adjacent to each other.

Even when one organic light-emitting layer is commonly disposed over four adjacent light-emitting regions, the anode electrodes are separated from each other and are independently controlled, so that the four light-emitting regions may emit light, respectively.

The upper common layer 147 may be disposed on the organic light-emitting layers 145R and 145B. As an example, the upper common layer 147 may be continuously and commonly disposed across all pixels of the display area AA. As an example, the upper common layer 147 may include an electron transport layer and an electron injection layer. Embodiments are not limited thereto. As an example, the upper common layer 147 may be separately disposed for each of pixels of the display area AA, or may be separately disposed for each light-emitting region group, without being limited thereto. As an example, the upper common layer 147 may be continuously and commonly disposed across all light-emitting regions of each light-emitting region group, without being limited thereto.

As an example, the cathode electrode 145 may be continuously and commonly disposed across all pixels of the display area AA, or may be separately disposed for each of pixels of the display area AA. In a top emission type organic light-emitting display device, the cathode electrode 145 may be formed as a transparent conductive film made of, for example, indium-tin-oxide (ITO) or indium-zinc-oxide (IZO), without being limited thereto.

An encapsulation layer 150 for suppressing moisture penetration may be further disposed on the cathode electrode 145. As an example, the encapsulation layer 150 may include a first inorganic encapsulation layer 152, an organic encapsulation layer 154, and a second inorganic encapsulation layer 156 which are sequentially stacked, without being limited thereto.

Each of the first inorganic encapsulation layer 152 and the second inorganic encapsulation layer 156 of the encapsulation layer 150 may be made of an inorganic insulating material such as silicon oxide (SiOx) or silicon nitride (SiNx), without being limited thereto. The organic encapsulation layer 154 of the encapsulation layer 150 may be made of an organic insulating material such as acryl resin, epoxy resin, phenolic resin, polyamide resin, and polyimide resin, without being limited thereto.

As an example, a touch sensor and an optical film may be disposed on the encapsulation layer 150, without being limited thereto.

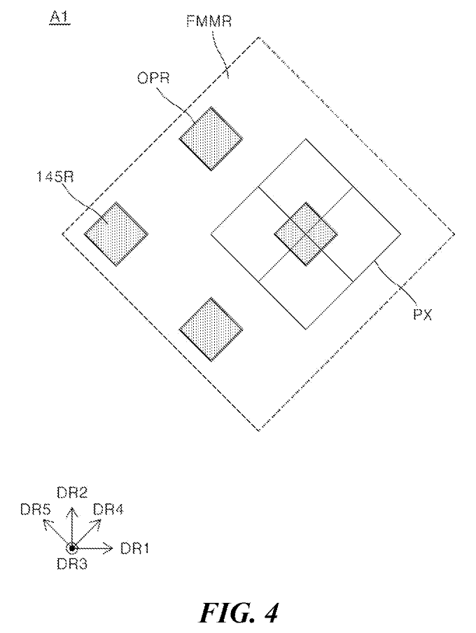

FIG. 4 illustrates a process of depositing a red organic light-emitting layer using a fine metal mask in an exemplary embodiment of the present disclosure. FIG. 4 illustrates the same area as that of FIG. 2.

Referring to FIG. 4, the first organic light-emitting layer 145R may be simultaneously deposited on the first sub-pixels of four pixels PX adjacent to each other through first openings OPR defined in a first fine metal mask FMMR. The first opening OPR may have, for example, a square shape. However, embodiments of the present disclosure are not limited thereto. The shape in the plan view of the first opening OPR may be variously changed according to a shape in the plan view of the first light-emitting region EAR. As an example, the shape in the plan view of the first opening OPR may be a combination of the shapes in plan view of the first light-emitting regions EAR of four pixels PX adjacent to each other, without being limited thereto. As an example, the area of the first opening OPR may be equal to or greater than a sum of areas of the first light-emitting regions EAR of four pixels PX adjacent to each other, without being limited thereto.

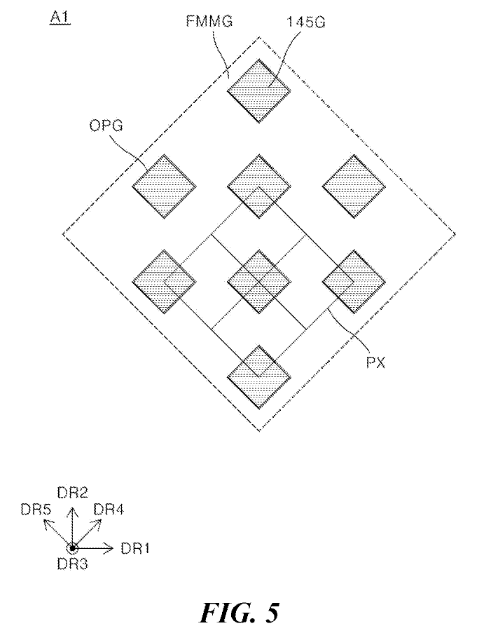

FIG. 5 illustrates depositing a green organic light-emitting layer using a fine metal mask in an exemplary embodiment of the present disclosure. FIG. 5 shows the same area as that of FIG. 2.

Referring to FIG. 5, the second organic light-emitting layer 145G may be simultaneously deposited on the second sub-pixels of four adjacent pixels PX through second openings OPG defined in a second fine metal mask FMMG. The second opening OPG may have, for example, a square shape. However, embodiments of the present disclosure are not limited thereto. The shape in the plan view of the second opening OPG may be variously changed according to a shape in the plan view of the second light-emitting region EAG.

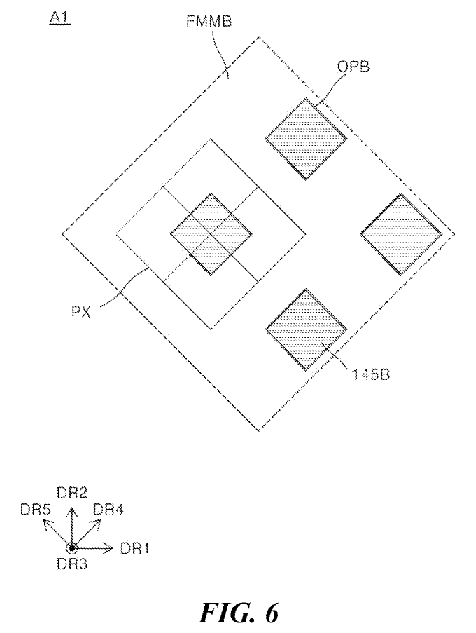

FIG. 6 illustrates depositing a blue organic light-emitting layer using a fine metal mask in an exemplary embodiment of the present disclosure. FIG. 6 illustrates the same area as that of FIG. 2.

Referring to FIG. 6, the third organic light-emitting layer 145B may be simultaneously deposited on the third sub-pixels PX of four adjacent pixels PX through third openings OPB defined in a third fine metal mask FMMB. The third opening OPB may have, for example, a square shape. However, embodiments of the present disclosure are not limited thereto. The shape in the plan view of the third opening OPBR may be variously changed according to a shape in the plan view of the third light-emitting region EAB.

According to an exemplary embodiment of the present disclosure, a pixel arrangement having a new structure in which a single organic light-emitting layer is continuously and commonly disposed over the respective sub-pixels emitting light of the same color of the four adjacent pixels may be applied, such that the resolution (pixel density) of the organic light-emitting display device may be improved four times even when a conventional fine metal mask is used.

According to an exemplary embodiment of the present disclosure, since it is unnecessary to reduce a spacing between different light-emitting regions in each pixel to improve the resolution, color mixing defect due to an alignment error of the fine metal mask may be prevented or reduced while improving the resolution.

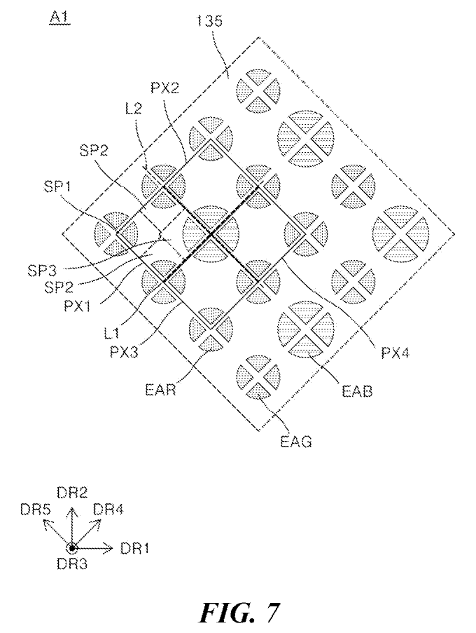

FIGS. 7 to 12 are plan views illustrating pixel arrangements according to various exemplary embodiments of the present disclosure. As described below with reference to FIGS. 7 to 12, the shapes of the first to third light-emitting regions EA1 to EA3 may be the same as or different from each other.

Referring to FIG. 7, unlike the exemplary embodiment illustrated in FIG. 2, in the present exemplary embodiment, each of the first to third light-emitting regions EAR, EAG, and EAB may have a fan shape having a central angle of 90 degrees. The exemplary embodiment illustrated in FIG. 7 is the same as the exemplary embodiment of FIG. 2 except for the shapes of the first to third light-emitting regions EAR, EAG, and EAB. In this case, the openings defined in each of the first to third fine metal masks for depositing the first to third organic light-emitting layers may have, for example, a circular shape.

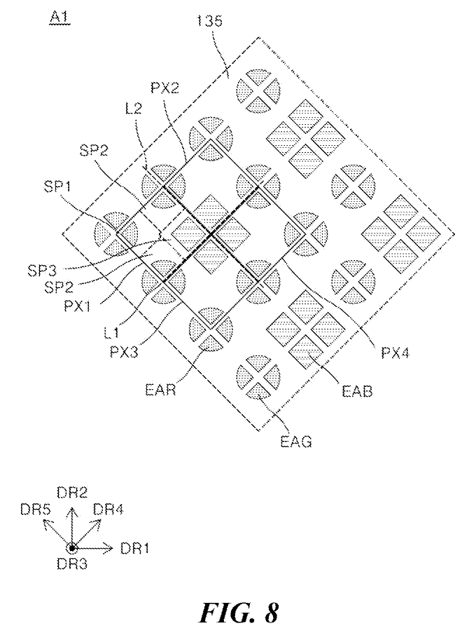

Referring to FIG. 8, unlike the exemplary embodiment illustrated in FIG. 2, in the present exemplary embodiment, each of the first and second light-emitting regions EAR and EAG may have a fan shape having a central angle of 90 degrees, and the third light-emitting region EAB may have a square shape. The exemplary embodiment illustrated in FIG. 8 is the same as the exemplary embodiment of FIG. 2 except for the shapes of the first and second light-emitting regions EAR and EAG. In this case, the openings defined in each of the first and second fine metal masks for depositing the first and second organic light-emitting layers may have, for example, a circular shape, and the openings defined in the third fine metal mask for depositing the third organic light-emitting layer may have, for example, a square shape.

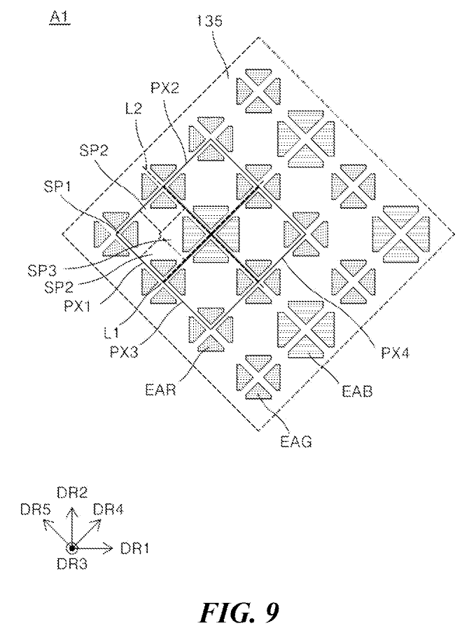

Referring to FIG. 9, unlike the exemplary embodiment shown in FIG. 2, in the present exemplary embodiment, each of the first to third light-emitting regions EAR, EAG, and EAB may have a pentagonal shape. The exemplary embodiment illustrated in FIG. 9 is the same as the exemplary embodiment of FIG. 2 except for the shapes of the first to third light-emitting regions EAR, EAG, and EAB. In this case, the openings defined in each of the first to third fine metal masks for depositing the first to third organic light-emitting layers may have, for example, a cross shape.

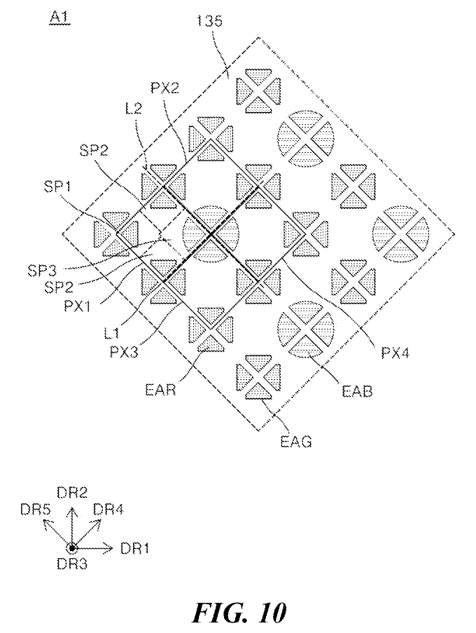

Referring to FIG. 10, unlike the exemplary embodiment illustrated in FIG. 2, in the present exemplary embodiment, each of the first and second light-emitting regions EAR and EAG may have a pentagonal shape, and the third light-emitting region EAB may have a fan shape having a central angle of 90 degrees. The exemplary embodiment illustrated in FIG. 10 is the same as the exemplary embodiment of FIG. 2 except for the shapes of the first to third light-emitting regions EAR, EAG, and EAB. In this case, the openings defined in each of the first and second fine metal masks for depositing the first and second organic light-emitting layers may have, for example, a cross shape, and the openings defined in the third fine metal mask for depositing the third organic light-emitting layer may have, for example, a circular shape.

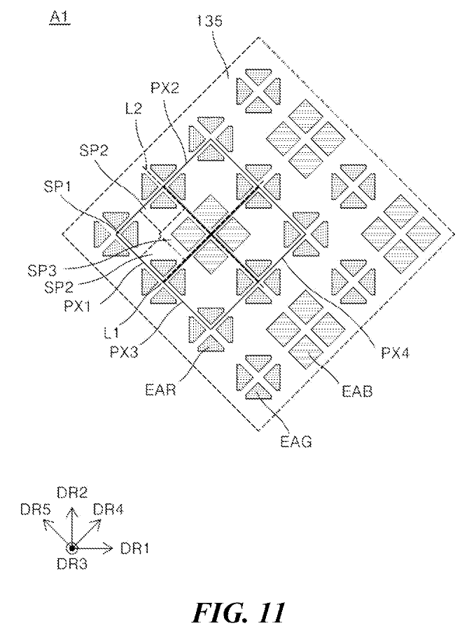

Referring to FIG. 11, unlike the exemplary embodiment illustrated in FIG. 2, in the present exemplary embodiment, each of the first and second light-emitting regions EAR and EAG may have a pentagonal shape, and the third light-emitting region EAB may have a square shape. The exemplary embodiment illustrated in FIG. 11 is the same as the exemplary embodiment of FIG. 2 except for the shapes of the first and second light-emitting regions EAR and EAG. In this case, the openings defined in each of the first and second fine metal masks for depositing the first and second organic light-emitting layers may have, for example, a cross shape, and the openings defined in the third fine metal mask for depositing the third organic light-emitting layer may have, for example, a square shape.

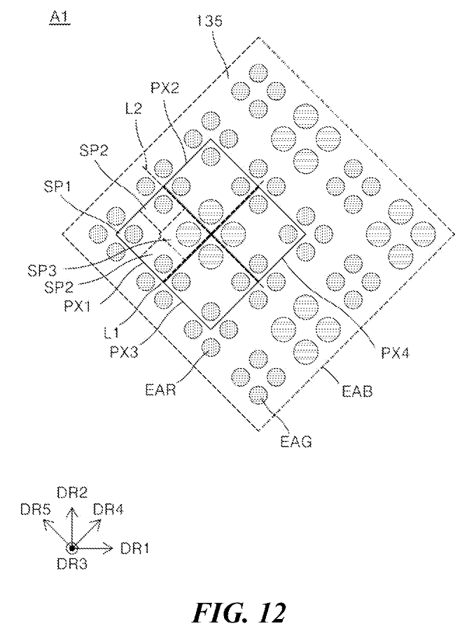

Referring to FIG. 12, unlike the exemplary embodiment illustrated in FIG. 2, in the present exemplary embodiment, each of the first to third light-emitting regions EAR, EAG, and EAB may have a circular shape. The exemplary embodiment illustrated in FIG. 12 is the same as the exemplary embodiment of FIG. 2 except for the shapes of the first to third light-emitting regions EAR, EAG, and EAB. In this case, the openings defined in each of the first to third fine metal masks for depositing the first to third organic light-emitting layers may have, for example, a square shape.

In addition to the exemplary embodiments as described with reference to FIGS. 7 to 12, combinations of various shapes may be applied to the shapes of the first to third light-emitting regions EAR, EAG, and EAB.

Although a case in which the shape of each of the third light-emitting regions EAB are different from each of the shapes of the first and second light-emitting regions EAR and EAG has been described above with reference to FIGS. 8, 10, and 11, embodiments of the present disclosure are not limited thereto. The shape of each of the first light-emitting regions EAR may be different from the shape of each of the second and third light-emitting regions EAG and EAB. The shape of each of the second light-emitting regions EAG may be different from the shape of each of the first and third light-emitting regions EAR and EAB. The shapes of the first light-emitting regions EAR, the second light-emitting regions EAG, and the third light-emitting regions EAB may be different from each other.

The display devices according to various exemplary aspects and exemplary embodiments of the present disclosure may be described as follows.

A first exemplary aspect of the present disclosure provides an organic light-emitting display device comprising: a plurality of pixels arranged in a first direction and a second direction perpendicular to each other, wherein each of the pixels includes one first light-emitting region, two second light-emitting regions, and one third light-emitting region, wherein the first to third light-emitting regions of one of two pixels adjacent to each other along the first direction and the first to third light-emitting regions of the other of the two pixels adjacent to each other along the first direction are arranged linearly symmetrically with each other around a first symmetry axis parallel to the second direction, wherein the first to third light-emitting regions of one of two pixels adjacent to each other along the second direction and the first to third light-emitting regions of the other of the two pixels adjacent to each other along the second direction are arranged linearly symmetrically with each other around a second symmetry axis parallel to the first direction.

In accordance with some exemplary embodiments of the first aspect of the present disclosure, a spacing between respective two light-emitting regions emitting light of the same color of two adjacent pixels is smaller than a spacing between two light-emitting regions emitting light of different colors in each pixel.

In accordance with some exemplary embodiments of the first aspect of the present disclosure, respective four light-emitting regions emitting light of the same color of four adjacent pixels are disposed adjacent to each other.

In accordance with some exemplary embodiments of the first aspect of the present disclosure, the four light-emitting regions disposed adjacent to each other have the same shape in a plan view of the display device, and are arranged so as to be linearly-symmetrical with each other around each of the first and second symmetry axes respectively parallel to the first direction and the second direction.

In accordance with some exemplary embodiments of the first aspect of the present disclosure, a single organic light-emitting layer is continuously and commonly disposed across the four light-emitting regions adjacent to each other.

In accordance with some exemplary embodiments of the first aspect of the present disclosure, respective first light-emitting regions of four pixels adjacent to each other are arranged so as to be rotationally-symmetrical with each other around a symmetry point between the four pixels, wherein respective second light-emitting regions of the four pixels adjacent to each other are arranged so as to be rotationally-symmetrical with each other around the symmetry point between the four pixels, wherein respective third light-emitting regions of the four pixels adjacent to each other are arranged so as to be rotationally-symmetrical with each other around the symmetry point between the four pixels.

In accordance with some exemplary embodiments of the first aspect of the present disclosure, the first light-emitting region is a red light-emitting region, the second light-emitting region is a green light-emitting region, and the third light-emitting region is a blue light-emitting region.

In accordance with some exemplary embodiments of the first aspect of the present disclosure, an area in a plan view of the third light-emitting region is greater than an area in a plan view of the first light-emitting region.

In accordance with some exemplary embodiments of the first aspect of the present disclosure, a shape in the plan view of the third light-emitting region is different from a shape in the plan view of the first light-emitting region.

A second aspect of the present disclosure provides an organic light-emitting display device comprising: first light-emitting region groups, each group including four first light-emitting regions spaced apart from each other; second light-emitting region groups, each group including four second light-emitting regions spaced apart from each other; and third light-emitting region groups, each group including four third light-emitting regions spaced apart from each other, wherein the first light-emitting region groups and the second light-emitting region groups are alternately arranged with each other along a first line extending in a first direction, wherein the second light-emitting region groups and the third light-emitting region groups are alternately arranged with each other along a second line, wherein the second line is spaced apart from the first line in a second direction perpendicular to the first direction and extends in the first direction and in parallel with the first line.

In accordance with some exemplary embodiments of the second aspect of the present disclosure, the four first light-emitting regions of each of the first light-emitting region groups have the same shape, and are arranged so as to be linearly-symmetrical with each other around each of first and second symmetry axes parallel to the first direction and the second direction.

In accordance with some exemplary embodiments of the second aspect of the present disclosure, the four second light-emitting regions of each of the second light-emitting region groups have the same shape, and are arranged so as to be linearly-symmetrical with each other around each of first and second symmetry axes parallel to the first direction and the second direction.

In accordance with some exemplary embodiments of the second aspect of the present disclosure, the four third light-emitting regions of each of the second light-emitting region groups have the same shape, and are arranged so as to be linearly-symmetrical with each other around each of first and second symmetry axes parallel to the first direction and the second direction.

In accordance with some exemplary embodiments of the second aspect of the present disclosure, a single first organic light-emitting layer is continuously and commonly disposed across the four first light-emitting regions.

In accordance with some exemplary embodiments of the second aspect of the present disclosure, a single second organic light-emitting layer is continuously and commonly disposed across the four second light-emitting regions.

In accordance with some exemplary embodiments of the second aspect of the present disclosure, a single third organic light-emitting layer is continuously and commonly disposed across the four third light-emitting regions.

In accordance with some exemplary embodiments of the second aspect of the present disclosure, the first light-emitting regions are red light-emitting regions, wherein the second light-emitting regions are green light-emitting regions, wherein the third light-emitting regions are blue light-emitting regions.

In accordance with some exemplary embodiments of the second aspect of the present disclosure, an area in a plan view of each of the third light-emitting regions is greater than an area in a plan view of each of the first light-emitting regions.

In accordance with some exemplary embodiments of the second aspect of the present disclosure, a shape in a plan view of the third light-emitting region is different from a shape in a plan view of the first light-emitting region.

Although some exemplary embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light-emitting display device comprising:
a plurality of pixels arranged in a first direction and a second direction transverse to each other; and
wherein each of the pixels of the plurality includes a plurality of light-emitting regions,
wherein the plurality of light-emitting regions of one of two pixels adjacent to each other along the first direction and the plurality of light-emitting regions of the other of the two pixels adjacent to each other along the first direction are arranged linearly symmetrically with each other around a first symmetry axis parallel to the second direction, and
wherein the plurality of light-emitting regions of one of two pixels adjacent to each other along the second direction and the plurality of light-emitting regions of the other of the two pixels adjacent to each other along the second direction are arranged linearly symmetrically with each other around a second symmetry axis parallel to the first direction.

2. The organic light-emitting display device of claim 1, wherein a spacing between respective two light-emitting regions emitting light of the same color of two adjacent pixels is smaller than a spacing between two light-emitting regions emitting light of different colors in each pixel.

3. The organic light-emitting display device of claim 1, wherein respective four light-emitting regions emitting light of the same color of four adjacent pixels are disposed adjacent to each other.

4. The organic light-emitting display device of claim 3, wherein the four light-emitting regions disposed adjacent to each other have the same shape in a plan view of the organic light-emitting display device, and are arranged so as to be linearly-symmetrical with each other around each of the first and second symmetry axes, respectively.

5. The organic light-emitting display device of claim 3, wherein a single organic light-emitting layer is continuously and commonly disposed across the four light-emitting regions adjacent to each other.

6. The organic light-emitting display device of claim 1, wherein the plurality of light-emitting regions comprises one first light-emitting region, two second light-emitting regions, and one third light-emitting region.

7. The organic light-emitting display device of claim 6, wherein respective first light-emitting regions of four pixels adjacent to each other are arranged so as to be rotationally-symmetrical around a symmetry point between the four pixels,
wherein respective second light-emitting regions of the four pixels adjacent to each other are arranged so as to be rotationally-symmetrical around the symmetry point between the four pixels, and
wherein respective third light-emitting regions of the four pixels adjacent to each other are arranged so as to be rotationally-symmetrical around the symmetry point between the four pixels.

8. The organic light-emitting display device of claim 6, wherein the first light-emitting region is a red light-emitting region, the second light-emitting region is a green light-emitting region, and the third light-emitting region is a blue light-emitting region.

9. The organic light-emitting display device of claim 6, wherein an area in a plan view of the third light-emitting region is greater than an area in a plan view of the first light-emitting region or an area in a plan view of the second light-emitting region.

10. The organic light-emitting display device of claim 6, wherein a shape in the plan view of the third light-emitting region is different from a shape in the plan view of the first light-emitting region or a shape in a plan view of the second light-emitting region.

11. The organic light-emitting display device of claim 1, wherein a shape in the plan view of one of the plurality of light-emitting regions is different from a shape in the plan view of another one of the plurality of light-emitting regions.

12. The organic light-emitting display device of claim 1, wherein the plurality of pixels are arranged in a display area having a rectangular shape defined by a third direction and a fourth direction different from the first direction and the second direction.

13. The organic light-emitting display device of claim 1, wherein the plurality of light-emitting regions included in each pixel are disposed adjacent to a plurality of corners of each pixel, respectively.

14. An organic light-emitting display device comprising:
first light-emitting region groups, each group including four first light-emitting regions spaced apart from each other;
second light-emitting region groups, each group including four second light-emitting regions spaced apart from each other; and
third light-emitting region groups, each group including four third light-emitting regions spaced apart from each other,
wherein the first light-emitting region groups and the second light-emitting region groups are alternately arranged with each other along a first line extending in a first direction,
wherein the second light-emitting region groups and the third light-emitting region groups are alternately arranged with each other along a second line, wherein the second line is spaced apart from the first line in a second direction transverse to the first direction and extends in the first direction and in parallel with the first line.

15. The organic light-emitting display device of claim 14, wherein the four first light-emitting regions of each of the first light-emitting region groups have the same shape, and are arranged so as to be linearly-symmetrical with each other around each of first and second symmetry axes parallel to the first direction and the second direction, respectively,
wherein the four second light-emitting regions of each of the second light-emitting region groups have the same shape, and are arranged so as to be linearly-symmetrical with each other around each of the first and second symmetry axes parallel to the first direction and the second direction, respectively, or
wherein the four third light-emitting regions of each of the second light-emitting region groups have the same shape, and are arranged so as to be linearly-symmetrical with each other around each of the first and second symmetry axes parallel to the first direction and the second direction, respectively.

16. The organic light-emitting display device of claim 14, wherein a single first organic light-emitting layer is continuously and commonly disposed across the four first light-emitting regions,
wherein a single second organic light-emitting layer is continuously and commonly disposed across the four second light-emitting regions, or
wherein a single third organic light-emitting layer is continuously and commonly disposed across the four third light-emitting regions.

17. The organic light-emitting display device of claim 14, wherein the first light-emitting regions are red light-emitting regions,
wherein the second light-emitting regions are green light-emitting regions, and
wherein the third light-emitting regions are blue light-emitting regions.

18. The organic light-emitting display device of claim 14, wherein an area in a plan view of each of the third light-emitting regions is greater than an area in a plan view of each of the first light-emitting regions or an area in a plan view of each of the second light-emitting regions.

19. The organic light-emitting display device of claim 14, wherein a shape in a plan view of the third light-emitting region is different from a shape in a plan view of the first light-emitting region or a shape in a plan view of the second light-emitting region.

20. An organic light-emitting display device comprising:
light-emitting region groups, each light-emitting region group including a plurality of light-emitting regions spaced apart from each other;
wherein the light-emitting region groups are arranged in a first direction and a second direction transverse to each other,
wherein the plurality of light-emitting regions included in each light-emitting region group are configured to emit light of the same color, and respective light-emitting regions included in adjacent light-emitting region groups are configured to emit light of different colors, and
wherein a single organic light-emitting layer is continuously and commonly disposed across the plurality of light-emitting regions included in each light-emitting region group.
